(19) United States
(12) Patent Application Publication
(10) Pub. No.: US 2020/0058899 A1
(43) Pub. Date: Feb. 20, 2020

(54) Sealant Tape and Method for Manufacturing the Same, Display Panel and Method for Manufacturing the Same

(71) Applicant: BOE TECHNOLOGY GROUP CO., LTD., Beijing (CN)

(72) Inventors: Dejun BU, Beijing (CN); Paoming TSAI, Beijing (CN)

(21) Appl. No.: 16/606,390

(22) PCT Filed: Dec. 11, 2018
(86) PCT No.: PCT/CN2018/120310

§ 371 Date: Oct. 18, 2019

(30) Foreign Application Priority Data
Dec. 15, 2017 (CN) 201711353229.3

(51) Int. Cl. H01L 51/52; H01L 51/00; H01L 27/32; G02F 1/1339; G02F 1/1333; C09J 7/40; C09J 7/30

(52) U.S. Cl. CPC H01L 51/5246; H01L 51/0097; H01L 27/3244; G02F 1/1339; G02F 1/133308; C09J 7/401; C09J 2483/00; G02F 2001/133317; G02F 2001/133331; C09J 2201/128; C09J 2203/326; C09J 2205/102; C09J 7/30

(57) ABSTRACT

Disclosed belongs to the technical field of displaying, and particularly relates to a sealant tape, a display panel and methods for manufacturing the same. The sealant tape comprises a substrate and an adhesive layer provided on at least one side of the substrate, wherein the substrate comprises a first elastomer, and the adhesive layer comprises a second elastomer and a crosslinking agent. Both of the substrate and the adhesive layer of the sealant tape are formed of elastomeric materials, and the adhesive layer further comprises a crosslinking agent to adjust the storage modulus thereof, such that the sealant tape can withstand a higher stress while provides excellent bending performance, and has a higher viscosity to ensure that it will not be unglued when the display panel is folded and thus it can be prevented from being damaged during folding or bending of the flexible display panel, ensuring good packaging performance.

### CROSS REFERENCE TO THE RELATED APPLICATION

The present application claims priority to the Chinese Patent Application No. 2017113532293 entitled “Sealant tape and method for manufacturing the same, display panel and method for manufacturing the same” filed on Dec. 15, 2017, the entire content of which is incorporated herein by reference.

### TECHNICAL FIELD

The present disclosure belongs to the technical field of displaying, and particularly relates to a sealant tape and a method for manufacturing the same, and a display panel and a method for manufacturing the same.

### BACKGROUND ART

The existing OLED (Organic Light-Emitting Diode) display devices and LCD (Liquid Crystal Display) display devices both comprise a plurality of layers, and thus it is necessary to apply a sealant in peripheral region as an adhesive and sealing member.

Each layers in the display device may be subjected to different degrees of stress, especially for the flexible display device which will be folded or bent in use, the cured sealant often leads to difficulties in bending, and is even damaged during bending, thereby affecting the reliability of the product.

It can be seen that to design a sealant capable of withstanding a higher stress to form a display device with higher reliability has become a technical problem to be solved at present.

### SUMMARY

The present disclosure provides a sealant tape and a method for manufacturing the same, and a display panel and a method for manufacturing the same.

The sealant tape according to the present disclosure comprises a substrate and an adhesive layer provided on at least one side of the substrate, wherein the substrate comprises a first elastomeric material and the adhesive layer comprises a second elastomeric material and a crosslinking agent.

Alternatively, the adhesive layer is provided on both sides of the substrate.

Alternatively, the first elastomeric material has an elasticity modulus of less than 100 MPa and a tensile strength of greater than 50 MPa.

Alternatively, the first elastomeric material comprises at least one of polyethylene terephthalate, polyethylene naphthalate, cycloolefin polymer, polyimide, polycarbonate and any combinations thereof

The second elastomeric material comprises at least one of acrylic resin, silicon-based resin, polyurethane resin, epoxy resin and any combinations thereof.

Alternatively, the crosslinking agent is organopolysiloxane having a CH₃—Si—H group. The organopolysiloxane has at least one or more of alkenyl group, hydroxyl group and methyl group on its side chain, and has an average molecular weight ranging from 500 to 1,500.

Alternatively, a light release film or a heavy release film is provided on the outer side of the adhesive layer away from the substrate.

Alternatively, the light release film is any one of polyethylene terephthalate, polyvinyl chloride, polycarbonate, polyethylene and polypropylene, and has a release force ranging from 2 to 20 g/f;

The heavy release film is any one of polyethylene terephthalate, polyvinyl chloride, polycarbonate, polyethylene and polypropylene, and has a release force ranging from 30 to 100 g/f.

The present disclosure also provides a method for manufacturing the above sealant tape comprising:

formulating a solution comprising at least a crosslinking agent, a second elastomeric material and a solvent for forming the adhesive layer;

applying the solution on both sides of the substrate; and

drying and curing the solution.

Alternatively, in the solution, the crosslinking agent is an organopolysiloxane containing CH₃—Si—H groups; the second elastomeric material comprises at least one of acrylic resin, silicon-based resin, polyurethane resin, epoxy resin and any combinations thereof; and the solvent comprises at least one or two of toluene and xylene.

Alternatively, the solution comprises 1 to 10 parts by weight of the crosslinking agent, 60 to 80 parts by weight of the second elastomeric material and 20 to 40 parts by weight of the solvent.

Alternatively, the solution further comprises an additive selected from at least one or more of a leveling agent, an antifoaming agent, a photoinitiator, and a viscosity improver, and each of the above additives ranges from 0.1 to 2 parts by weight.

The present disclosure further provides a display panel comprising a flexible display module encapsulated using the sealant tape described above.

Alternatively, a flexible cover plate is provided on the display side of the flexible display module and a middle frame is provided on the non-display side, wherein the sealant tape is provided in peripheral region between the flexible cover plate and the middle frame.

Alternatively, an ink layer is further provided between the flexible cover plate and the sealant tape, and a plurality of concave-convex structures are provided on one side of the ink layer and/or the middle frame towards the sealant tape.

Alternatively, each concave-convex structure has a three-dimension shape selected form any one or more of a hemisphere, a pyramid and a cube.

Alternatively, in a plane parallel to the display plane, the plurality of adjacent concave-convex structures has a cross-sectional shape selected from at least one or more of a triangle, a rectangle, a hexagon, a circle and an ellipse.

The present disclosure further discloses a method for manufacturing a display panel comprising:

manufacturing a flexible display device;

forming a structure including a plurality of concave-convex structures on the display side of the flexible display device;

attaching and bonding the flexible display device to form a primary flexible display module;

adhering a sealant tape in peripheral region of the primary flexible display module; and

adhering a middle frame on the non-display side of the primary flexible display module and then performing integrally pressing.

### BRIEF DESCRIPTION OF THE DRAWINGS

FIG. 1 is a schematic diagram of the structure after encapsulating by the sealant tape according to an embodiment of the present disclosure;

FIG. 2 is a cross-sectional diagram of the flexible display panel according to an embodiment of the present disclosure;

FIG. 3 is a cross-sectional diagram of the concave-convex structure of the flexible display panel according to another embodiment of the present disclosure;

FIGS. 4A to 4C are cross-sectional diagrams of the concave-convex structure in FIG. 3;

FIGS. 5A to 5C are schematic diagrams of the process for forming the flexible display panel according to an embodiment of the present disclosure.

### DETAILED DESCRIPTIONS

In order to make those skilled in the art better understand technical solutions of the present invention, the sealant tape and the method for manufacturing the same, and the display panel and the method for manufacturing the same according to the present disclosure will be further described in detail with reference to the accompanying drawings and specific embodiments below.

Directed to the problem that the hardened sealant often causes difficulties in. bending when the present flexible display device is bent, and that the hardened sealant is even damaged due to a higher stress during bending, thereby affecting the reliability of the product, some embodiments of the present disclosure provide a sealant tape and a method for manufacturing the same. The sealant tape according to the present disclosure has excellent bending performance, and can effectively reduce the stress on the frame of the flexible display panel when being bent, thereby avoiding the defects during folding or bending and ensuring no damage to the sealant tape in the flexible display panel.

According to an embodiment of the present disclosure, the sealant tape comprises a substrate formed of a first elastomeric material, and an adhesive layer formed of a second elastomeric material and a crosslinking agent symmetrically provided on both sides of the substrate.

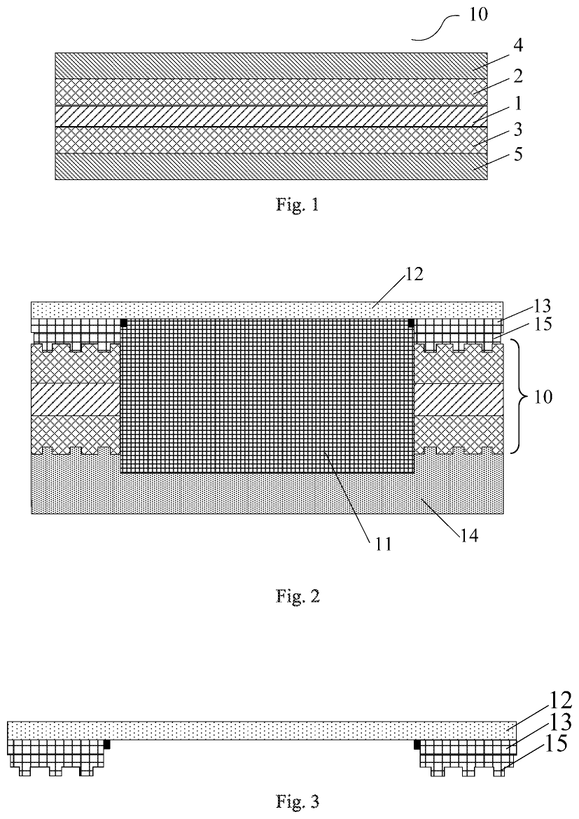

As shown in FIG. 1, the sealant tape 10 comprises a first adhesive layer 2, a substrate 1 and a second adhesive layer 3 which are laminated in this order.

The substrate 1 is formed of an elastomeric material having an elasticity modulus of less than 100 MPa and a tensile strength of greater than 50 MPa. As the center layer of the sealant tape, the substrate 1 formed of the polymer material having a higher elasticity can ensure the performance of the sealant tape as an elastomer. The substrate may be a commonly used flexible material such as at least one of polyethylene terephthalate (PET), polyethylene naphthalate (PEN), a cycloolefin polymer (COP), polyimide (PI), polycarbonates (PC) and any combinations thereof.

The first adhesive layer 2 and the second adhesive layer 3 are made of an elastomeric adhesive having a storage modulus ranging from 2 KPa to 80 KPa (@25° C., 1 Hz) and an adhesion of greater than 2 N/CM (@25° C.), thus the performance of the sealant tape as an elastomer can be ensured. The two adhesive layers may be at least one of acrylic resin, silicon-based resin, polyurethane resin, epoxy resin and any combinations thereof.

The crosslinking agent is used to adjust the storage modulus of the adhesive layers. The adhesive layers have a storage modulus ranging from about 2×10³ Pa to 8×10⁴ Pa at about 25° C. When the storage modulus is within the above range, the adhesive layers can exhibit sufficient viscosity and can be easily bent by an external force. In order to ensure the elasticity, the adjustment of the storage modulus is achieved by adding a crosslinking agent. The crosslinking agent may be an organopolysiloxane containing CH₃—Si—H group. The organopolysiloxane may have at least one or more of alkenyl group, hydroxyl group, and methyl group on its side chain, and have an average molecular weight ranging from 500 to 1,500.

According to other embodiments of the present disclosure, the sealant tape may further comprise a light release film 4 located on the outer side of the first adhesive layer 2, and a heavy release film 5 located on the outer side of the second adhesive layer 3. The light release film 4 and the heavy release film 5 play a role of protecting the body of the sealant tape composed of the substrate 1 and the adhesive layers. When the sealant tape 10 is used in encapsulating a display device, the light release film 4 is peeled off firstly and then the sealant tape 10 is attached and fixed. After the sealant tape 10 is fixed, the heavy release film 5 is peeled off then and the subsequent encapsulating is performed.

In a specific embodiment, the light release film 4 may be any one of polyethylene terephthalate (PET), polyvinyl chloride (PVC), polycarbonate (PC), polyethylene (PE) and polypropylene (PP). The light release film 4 may have a thickness of 25 to 75 μm and a release force of 2 to 20 g/f. The heavy release film 5 may also be any one of PET, PVC, PC, PE and PP. The heavy release film 5 may have a thickness of 50 μm to 125 μm and a release force of 30 to 100 g/f The light release film 4 and the heavy release film 5 described above are referred to based on the release force, and may be the same material. The above materials are easy to obtain and use, and have a good protective effect.

The above sealant tape has good bending performance, and the sealant tape can be prevented from being damaged during bending.

Correspondingly, some embodiments of the present disclosure further provide a method for manufacturing the above-mentioned sealant tape comprising:

formulating a solution for forming the adhesive layer with the second elastomeric material and the crosslinking agent;

applying the solution on both sides of the substrate 1; and

drying and curing the solution.

Each steps of the method for manufacturing the sealant tape 10 will be described below in detail.

The method for manufacturing the sealant tape comprises the following specific steps:

S1): formulating a solution for forming the adhesive layer.

In this step, the components and amounts in the solution are listed as follows:

The crosslinking agent is an organopolysiloxane containing CH₃—Si—H group and accounts for 1 to 10 parts by weight.

The second elastomer is at least one of an acrylic resin, a silicon-based resin, a polyurethane resin, an epoxy resin or any combinations thereof, and accounts for 60 to 80 parts by weight in total.

The solvent is any one of toluene and xylene or a mixture thereof, and accounts for 20 to 40 parts by weight.

The additives includes but not limited to, for example, a leveling agent, an antifoaming agent, a photoinitiator, a viscosity improver or other analogues, and accounts for 0.1 to 2 parts by weight respectively.

S2): applying the solution on both sides of the substrate, and then drying and curing the solution.

The solution for forming the adhesive layer can be applied by a conventional coating method such as dip coating, spray coating, blade coating, bar coating, slit extrusion coating, spin coating, gravure printing, ink jet printing and the like.

The solution can be cured by a conventional curing method, either by photo curing method (UV curing or other radiation curing) or by thermal curing method. Since the solution comprises the crosslinking agent, which results a smaller modulus of the obtained adhesive layer to exhibit an elastomeric form.

S3): Attaching the light release film and the heavy release film.

In this step, the light release film and the heavy release film are attached on the outsides of the two adhesive layers, respectively. That is, the light release film is attached on the outside of the first adhesive layer, and the heavy release film is attached on the outside of the second adhesive layer.

By using the above method, a sealant tape with better encapsulation performance can be obtained.

In the present rigid display device, the sealant is polymerized in-site to form a glassy solid, thereby bonding the upper and lower substrates together. The hardened sealant has a Young's modulus of a GPa level which is not resistant to bending, thus cannot be suitable for flexible display devices.

In contrast, the sealant tape of the present disclosure has a substrate and an adhesive layer both formed of an elastomeric material, and the adhesive layer further comprises a crosslinking agent to adjust the storage modulus of the adhesive layer, so that the sealant tape has a higher adhesiveness and an excellent bending performance at the same time, which could ensure the sealant not being unglued when the display panel is folded.

When the sealant tape of the present disclosure is applied to a flexible display device, it is capable of withstanding a higher stress, and thus the sealant tape can be prevented from being damaged during folding or bending of the flexible display panel, thereby ensuring good encapsulation performance.

Some embodiments of the present disclosure provide a display panel comprising a flexible display module encapsulated by using the sealant tape described above. The sealant tape can effectively reduce the stress on the frame of the flexible display device when being bent, thus the display panel of the present disclosure can ensure the performance as being folded or bent and has a better encapsulation performance while achieving the flexible display.

The flexible display module herein can be an LCD display device or an OLED display device.

In the flexible display panel according to an embodiment of the present disclosure, as shown in. FIG. 2, a flexible cover plate 12 and a middle frame 14 are provided on two opposite sides of the flexible display panel, respectively. The flexible cover plate 12 is configured to protect the display module 11. The middle frame 14 is configured to support the display module 11. The sealant tape 10 is provided in a peripheral region between the flexible cover plate 12 and the middle frame 14.

The flexible cover plate 12 is usually any one of a transparent plastic cover, an ultra-thin glass or the combination thereof The transparent plastic cover is usually any one of polyethylene terephthalate (PET), polyethylene naphthalate (PEN), a cycloolefin polymer (COP), transparent polyimide (CPI) and polycarbonate (PC), or any combinations thereof An ink layer 13 is provided in the peripheral region of the flexible cover plate on the side towards the display module, and a plurality of concave-convex structures 15 are provided on the inner side of the ink layer 13 and/or of the middle frame 14. That is, the concave-convex structure 15 can be formed only on the inner side of the ink layer 13, only on one side of the middle frame 14, or both on the inner sides of the ink layer 13 and of the middle frame 14. The flexible display panel in FIG. 2 is schematically illustrated by providing the concave-convex structure on both inner sides of the ink layer 13 and of the middle frame 14.

The concave-convex structure 15 can effectively reduce the stress on the frame of the flexible display device when being bent, and effectively block the path of moisture and oxygen penetrating into the display panel structure through the flexible display module 11, thereby improving the performance of the flexible display panel and extending its lifetime.

As shown in FIG. 3, in some embodiments, each concave-convex structure 15 may have a three-dimensional shape of any one or more regular shape(s), such as a hemisphere, a pyramid and a cube. The concave-convex structure 15 can effectively improve the adhesion of the sealant tape and enhance the adhesive degree between the sealant tape and the frame when the display panel is folded or bent, thereby ensuring a good encapsulation performance. It is readily understand that the concave-convex structure 15 may also be an irregular shape, as long as the adhesive degree between the sealant tape and the frame can be enhanced to ensure the encapsulation performance when folding or bending. The irregular shape is not limited herein.

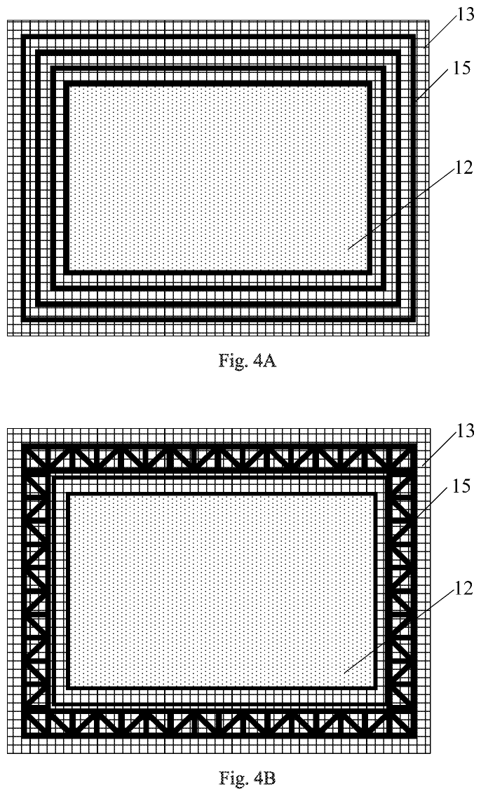

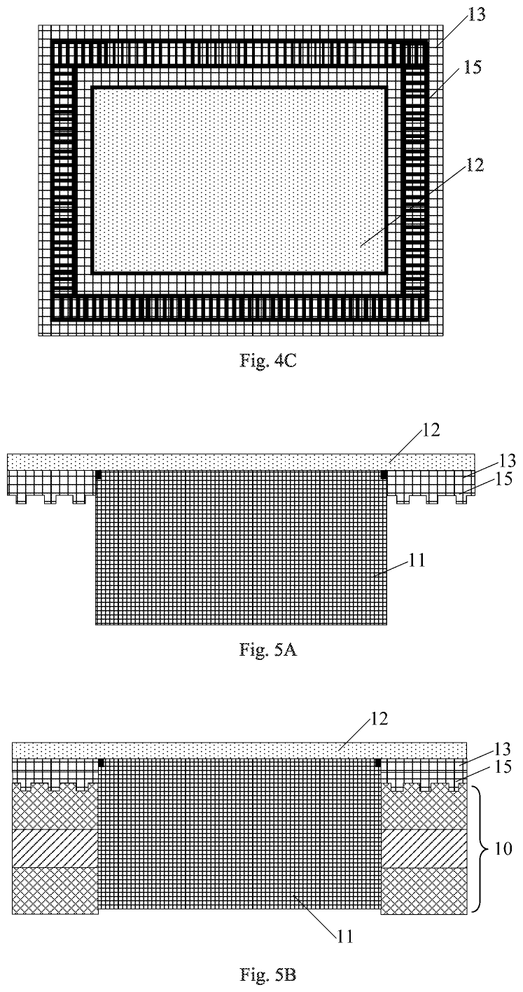

As shown in FIGS. 4A to 4C, in a plane parallel to the substrate, the plurality of adjacent concave-convex structures 15 have a regular cross-sectional shape, such as a triangle, a rectangle, a hexagon, a circle, an ellipse and the like. The cross-sectional shape may also be an irregular shape, provided that on one hand the process for forming the concave-convex structures is simple and that on the other hand the adhesive degree between the sealant tape and the frame can be ensured.

Depending on the material of the concave-convex structure 15, a screen printing process, a laser method or a physical rubbing method can be selected. Alternatively, the concave-convex structure 15 on the ink layer 13 is formed by a screen printing process; and the concave-convex structure 15 on the middle frame 14 is formed by a laser method or a physical rubbing method.

Hereinafter, taking an OLED display device as an example of the flexible display module, a method for manufacturing the flexible display panel will be described.

S1: manufacturing a flexible display device.

The flexible OLED display device may be a foldable active matrix organic light emitting diode (AMOLED), which typically comprises a flexible cover plate, a touch screen panel (TSP), a circular polarizer (CPOL), a flexible display panel and a bottom film laminated in this order, and a flexible cover plate 12 (on the display side, that is, the side usually towards the user to view the program), a middle frame 14 (on the non-display side, that is, the side away from the user) and the like are provided on two opposite sides of the display module. A heat dissipation module may also be provided as appropriate, which will not be described in detail herein.

In order to ensure the production efficiency, a plurality of flexible display devices is usually formed on one substrate simultaneously. As a typical flexible display device, an OLED display device has a structural comprising a bottom film, a substrate, a thin film transistor, an OLED, a thin film encapsulation layer and the like. The bottom film may be made of PET, The substrate may be made of PL The thin film transistor (TFT) may be LTPS type or other types. The thin film encapsulation (TFE) layer may be any suitable TFE, which is not limited herein.

Generally, manufacturing a flexible display device comprises the following steps: forming a flexible substrate base, a thin film transistor, an OLED (including at least an anode layer, an organic light emitting layer and a cathode layer) and a thin film encapsulation layer on a rigid substrate; then peeling off the rigid substrate and the flexible substrate base with a laser radiation; finally adhering a bottom film on the side of the flexible substrate base away from the thin film transistor.

After the above steps are completed, the substrate is cut and divided into a plurality of independent OLED display devices.

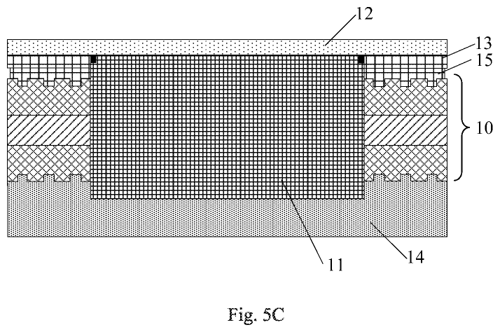

Next, the subsequent processes are further continued to form a display module with reference to FIGS. 5A to 5C.

S2: Forming a layer comprising a plurality of concave-convex structures on the display side of the flexible display device.

In this step, as shown in FIG. 5A, the concave-convex structures 15 are provided in the peripheral region on the display side of the flexible display device. For the flexible OLED display panel, the concave-convex structures 15 are provided by a screen printing process in the ink layer 13.

The steps for forming the concave-convex structures 15 in the ink layer 13 comprises: firstly, forming an ink layer 13 with a total thickness of the printed ink of about 5 to 40 μm by printing an ink on the flexible cover plate 12; next, treating the ink layer 13 by a screen printing process to forming a plurality of concave-convex structures 15 having a thickness of 0.1 μm to 20 μm in the upper portion of the ink layer 13.

The ink layer 13 is used to cover the traces at the edges of the touch screen and the display module. The flexible cover plate 12 is usually any one of a transparent plastic cover and an ultra-thin glass or the combination thereof The transparent plastic cover is usually any one of polyethylene terephthalate (PET), polyethylene naphthalate (PEN), a cycloolefin polymer (COP), transparent polyimide (CPI) and polycarbonate (PC), or any combinations thereof

In this step, each concave-convex structure 15 may have a regular three-dimensional shape, such as a hemisphere, a pyramid or a rectangle. In the plane parallel to the substrate, the plurality of adjacent concave-convex structures 15 may constitute a regular cross-sectional shape, such as a triangle, a rectangle, a square, a hexagon, a circle and an ellipse; or an irregular shape, which will not be described in detail herein.

S3: Attaching and bonding the flexible display device to form a primary flexible display module.

In this step, the display module is treated by a module process. The module process mainly includes an attaching process and a bonding process. Usually, the module process comprises the following steps: firstly attaching a circular polarizer (CPOL) to a flexible display device; then binding a driver chip to the flexible display device; and attaching a touch screen panel (TSP) and a flexible cover plate 12 sequentially by using an optical clear adhesive (OCA), thereby obtaining a primary flexible display module having a structure as shown in FIG. 5A.

S4: Adhering a sealant tape in a peripheral region of the primary flexible display module.

In this step, as shown in FIG. 5B, the sealant tape 10 manufactured previously is used. Firstly, the light release film 4 is peeled off, and the sealant tape 10 is attached and fixed in the peripheral region of the primary flexible display module. In fact, the sealant tape 10 may be manufactured at the same time by different production lines with the flexible display panel or manufactured separately in advance, as long as it can be manufactured just before final encapsulation. For this, it is not limited herein.

S5. Adhering a middle frame on the non-display side of the primary flexible display module and performing integrally pressing.

In this step, the heavy release film 5 of the sealant tape 10 is peeled off and the sealant tape 10 is bonded to the middle frame 14. Then the flexible display module is integrally pressed. The sealant tape is filled into the concave-convex structure formed in the ink layer 13 and the middle frame 14 due to being pressed, so as to achieve the encapsulation of the flexible display module as shown in FIG. 5C.

Alternatively, the concave-convex structure 15 is formed in the middle frame 14 before the middle frame is attached. The method for forming the concave-convex structure 15 in the middle frame 14 depends on the material of the middle frame. If the middle frame 14 is made of plastic material, the concave-convex structure 15 may be formed by a laser method. If the middle frame 14 is made of a non-plastic material, the concave-convex structure 15 may be formed on the originally smooth surface by a physical rubbing method and the like.

Similarly, each concave-convex structure 15 may have a regular three-dimensional shape, such as a hemisphere, a pyramid or a rectangle. In the plane parallel to the substrate, the plurality of adjacent concave-convex structures 15 may constitute a regular cross-sectional shape, such as a triangle, a rectangle, a square, a hexagon, a circle and an ellipse; or an irregular shape, which will not be described in detail herein.

So far, the manufacturing of the flexible display panel is completed.

The display panel may be used for any product or component with display function, such as desktop computer, tablet computer, notebook computer, mobile phone, PDA, GPS, vehicle display, projected display, camera, digital camera, electronic watch, calculator, electronic instrument, meter, LCD panel, electronic paper, television, display and navigator, and can be applied to many fields such as public display and unreal display.

By using the sealant tape, the flexible display panel can effectively reduce the stress on the frame when the flexible display device is folded or bent, and effectively block a path of moisture and oxygen penetrating into the display panel structure through the display panel. Further, with the concave-convex structure provided in the ink layer and/or the middle frame of the display module, the bonding force between the sealant tape and the frame is enhanced, so as to ensure the encapsulation performance during bending or folding, and thereby extending the lifetime of the flexible display panel.

It can be understood that the foregoing embodiments are merely illustrative embodiments employed for describing the principle of the present invention. However, the present invention is not limited thereto. For a person of ordinary skill in the art, various deformations and improvements can be made without departing from the spirit and essence of the present invention. These deformations and modifications shall fall into the protection scope of the present invention.

1-17. (canceled)

18. A sealant tape comprising a substrate and an adhesive layer on at least one side of the substrate, wherein the substrate comprises a first elastomeric material, and the adhesive layer comprises a second elastomeric material and a crosslinking agent.

19. The sealant tape according to claim 18, wherein the adhesive layer is on both sides of the substrate.

20. The sealant tape according to claim 18, wherein the first elastomeric material has an elastic modulus of less than 100 MPa and a tensile strength of greater than 50 MPa.

21. The sealant tape according to claim 18, wherein the first elastomeric material comprises at least one of polyethylene terephthalate, polyethylene naphthalate, a cycloolefin polymer, polyimide, polycarbonate or any combinations thereof; and
the second elastomeric material comprises at least one of an acrylic resin, a silicon-based resin, a polyurethane resin, an epoxy resin or any combinations thereof.

22. The sealant tape according to claim 18, wherein the crosslinking agent is an organopolysiloxane comprising CH₃—Si—H group; and the organopolysiloxane has at least one or more groups of alkenyl group, hydroxyl group and methyl group on the side chain, and has an average molecular weight ranging from 500 to 1,500.

23. The sealant tape according to claim 18, wherein there is a light release film or a heavy release film on the outer side of the adhesive layer away from the substrate.

24. The sealant tape according to claim 23, wherein the light release film is any one of polyethylene terephthalate, polyvinyl chloride, polycarbonate, polyethylene and polypropylene, which has a release force ranging from 2 to 20 g/f; and
the heavy release film is any one of polyethylene terephthalate, polyvinyl chloride, polycarbonate, polyethylene and polypropylene, which has a release force ranging from 30 to 100 g/f.

25. A method for manufacturing the sealant tape of claim 18, comprising:
formulating a solution for forming an adhesive layer, comprising at least a crosslinking agent, a second elastomeric material and a solvent;
applying the solution on both sides of the substrate; and
drying and curing the solution.

26. The method for manufacturing the sealant tape according to claim 25, wherein, in the solution,
the crosslinking agent, using an organopolysiloxane containing CH₃—Si—H groups;
the second elastomer, comprising at least one or more of an acrylic resin, a silicon-based resin, a polyurethane resin, and an epoxy resin; and
the solvent, comprising at least one or two of toluene and xylene.

27. The method of preparing the sealant tape according to claim 26, wherein the raw material components in the solution in parts by weight are respectively:
the crosslinking agent ranging from 1 to 10 parts by weight;
the second elastomer ranging from 60 to 80 parts by weight; and
the solvent ranging from 20 to 40 parts by weight.

28. The method of preparing the sealant tape according to claim 25, wherein the solution further comprises an additive, the additive comprises at least one or more of a leveling agent, an antifoaming agent, a photo initiator, and a viscosity improver, and each of the above additives ranges from 0.1 to 2 parts by weight.

29. A display panel, comprising a display region and a peripheral region surrounding the display region;
wherein the display panel comprises a flexible cover plate, a flexible display module in the display region, a sealant tape in the peripheral region, and an ink layer in the peripheral region;
the sealant type comprises a substrate and an adhesive layer on the side of the substrate towards to the ink layer, and the adhesive layer has a plurality of concave-convex structures;
the ink layer is located between the sealant type and the flexible cover plate, and a plurality of concave-convex structures are provided on one side of the ink layer towards the sealant tape so as to prohibit penetrating of oxygen and water and reduce stress; and
the concave-convex structures of the adhesive layer joint with the concave-convex structures of the ink layer.

30. The display panel according to claim 29, wherein a middle frame is provided on the non-display side and a plurality of concave-convex structures are provided on one side of the middle frame towards the sealant tape;
the sealant type further comprises an adhesive layer on the side of the substrate towards to the middle frame has a plurality of concave-convex structures; and
the concave-convex structures of the adhesive layer joint with the concave-convex structures of the middle frame.

31. The display panel according to claim 29, wherein the three-dimensional shape of the single concave-convex structure is any one or more of a hemisphere, a pyramid, and a cube.

32. The display panel according to claim 29, wherein the cross-sectional shape of the plurality of adjacent concave-convex structures in a plane parallel to the display plane includes at least one or more of a triangle, a rectangle, a hexagon, a circle, and an ellipse.
